(19) United States
(12) Patent Application Publication
(10) Pub. No.: US 2023/0420291 A1
(43) Pub. Date: Dec. 28, 2023

(54) PATTERN FORMING METHOD, TEMPLATE MANUFACTURING METHOD, AND SEMICONDUCTOR DEVICE MANUFACTURING METHOD

(71) Applicant: Kioxia Corporation, Tokyo (JP)

(72) Inventor: Masatoshi TERAYAMA, Kawasaki Kanagawa (JP)

(73) Assignee: Kioxia Corporation, Tokyo (JP)

(21) Appl. No.: 18/177,979

(22) Filed: Mar. 3, 2023

(30) Foreign Application Priority Data
Jun. 22, 2022 (JP) 2022-100723

(51) Int. Cl. H01L 21/768; H01L 21/027; G03F 7/00

(52) U.S. Cl. CPC H01L 21/76817; H01L 21/0271; H01L 21/76877; G03F 7/0002

(57) ABSTRACT

A pattern forming method includes: forming a second layer over a first layer; forming a first pattern along a surface of the second layer opposite to the first layer, the first pattern including an inclined portion with a recessed portion; and forming a second pattern on the first layer by performing, with the second layer as a mask, a first etching process to remove a part of the first layer.

### CROSS-REFERENCE TO RELATED APPLICATION

This application is based upon and claims the benefit of priority from Japanese Patent Application No. 2022-100723, filed Jun. 22, 2022, the entire contents of which are incorporated herein by reference.

### FIELD

Embodiments described herein relate generally to a pattern forming method, a template manufacturing method, and a semiconductor device manufacturing method.

### BACKGROUND

To increase the capacity of such a NAND flash memory, a three-dimensional NAND flash memory with a configuration in which many memory cells are stacked is in practical use. A plurality of conductive layers connected to each memory cell are stacked on a substrate and connected to a drive circuit or the like.

A contact connected to each of the plurality of conductive layers stacked on the substrate has a multi-gradation pattern in the stacking direction. Accordingly, nanoimprint lithography for forming a pattern by using a multi-gradation template to imprint on a resist is useful.

### DESCRIPTION OF THE DRAWINGS

FIG. 1 is a cross-sectional view illustrating the configuration of the pattern of a template according to one embodiment.

FIG. 2 is a cross-sectional view illustrating a template pattern forming method according to one embodiment.

FIG. 3 is a cross-sectional view illustrating a template pattern forming method according to one embodiment.

FIG. 4 is a cross-sectional view illustrating a template pattern forming method according to one embodiment.

FIG. 5 is a cross-sectional view illustrating a template pattern forming method according to one embodiment.

FIG. 6 is a cross-sectional view illustrating a template pattern forming method according to one embodiment.

FIG. 7 is a cross-sectional view illustrating a template pattern forming method according to one embodiment.

FIG. 8 is a perspective view illustrating an overall configuration of a semiconductor device according to one embodiment.

FIG. 9 is a perspective view illustrating the configurations of a memory cell region and a contact region of a semiconductor device according to one embodiment.

FIG. 10 is a cross-sectional view illustrating the configuration of a stacked wiring structure of a semiconductor device according to one embodiment.

FIG. 11 is a cross-sectional view illustrating a method for manufacturing a stacked wiring structure of a semiconductor device according to one embodiment.

FIG. 12 is a cross-sectional view illustrating a method for manufacturing a stacked wiring structure of a semiconductor device according to one embodiment.

FIG. 13 is a cross-sectional view illustrating a method for manufacturing a stacked wiring structure of a semiconductor device according to one embodiment.

FIG. 14 is a cross-sectional view illustrating a method for manufacturing a stacked wiring structure of a semiconductor device according to one embodiment.

FIG. 15 is a cross-sectional view illustrating the configuration of the pattern of a template according to one embodiment.

FIG. 16 is a cross-sectional view illustrating a template pattern forming method according to one embodiment.

FIG. 17 is a cross-sectional view illustrating a template pattern forming method according to one embodiment.

FIG. 18 is a cross-sectional view illustrating a template pattern forming method according to one embodiment.

FIG. 19 is a cross-sectional view illustrating a template pattern forming method according to one embodiment.

FIG. 20 is a cross-sectional view illustrating a template pattern forming method according to one embodiment.

FIG. 21 is a cross-sectional view illustrating the configuration of a stacked wiring structure according to one embodiment.

FIG. 22 is a cross-sectional view illustrating a method for manufacturing a stacked wiring structure of a semiconductor device according to one embodiment.

FIG. 23 is a cross-sectional view illustrating a method for manufacturing a stacked wiring structure of a semiconductor device according to one embodiment.

FIG. 24 is a cross-sectional view illustrating a method for manufacturing a stacked wiring structure of a semiconductor device according to one embodiment.

FIG. 25 is a cross-sectional view illustrating a method for manufacturing a stacked wiring structure of a semiconductor device according to one embodiment.

FIG. 26 is a cross-sectional view illustrating a template pattern forming method according to one embodiment.

FIG. 27 is a cross-sectional view illustrating a template pattern forming method according to one embodiment.

FIG. 28 is a cross-sectional view illustrating a template pattern forming method according to one embodiment.

FIG. 29 is a cross-sectional view illustrating a template pattern forming method according to one embodiment.

FIG. 30 is a cross-sectional view illustrating a template pattern forming method according to one embodiment.

FIG. 31 is a cross-sectional view illustrating a template pattern forming method according to one embodiment.

FIG. 32 is a cross-sectional view illustrating a template pattern forming method according to one embodiment.

FIG. 33 is a cross-sectional view illustrating a template pattern forming method according to one embodiment.

FIG. 34 is a cross-sectional view illustrating a template pattern forming method according to one embodiment.

FIG. 35 is a cross-sectional view illustrating a template pattern forming method according to one embodiment.

FIG. 36 is a cross-sectional view illustrating a template pattern forming method according to one embodiment.

FIG. 37 is a cross-sectional view illustrating a template pattern forming method according to one embodiment.

FIG. 38 is a cross-sectional view illustrating a template pattern forming method according to one embodiment.

FIG. 39 is a cross-sectional view illustrating a template pattern forming method according to one embodiment.

FIG. 40 is a cross-sectional view illustrating a template pattern forming method according to one embodiment.

FIG. 41 is a cross-sectional view illustrating a template pattern forming method according to one embodiment.

FIG. 42 is a cross-sectional view illustrating a template pattern forming method according to one embodiment.

FIG. 43 is a cross-sectional view illustrating a template pattern forming method according to one embodiment.

### DETAILED DESCRIPTION

Embodiments provide a pattern forming method, a template manufacturing method, and a semiconductor device manufacturing method improved in manufacturing efficiency and accuracy.

In general, according to one embodiment, a pattern forming method includes: forming a second layer over a first layer; forming a first pattern along a surface of the second layer opposite to the first layer, the first pattern including an inclined portion with a recessed portion; and forming a second pattern on the first layer by performing, with the second layer as a mask, a first etching process to remove a part of the first layer.

Hereinafter, a pattern forming method, a template manufacturing method, and a semiconductor device manufacturing method according to the present embodiment will be specifically described with reference to the drawings.

In the following description, elements substantially identical in function and configuration are given the same reference numerals or the same reference numerals followed by alphabets and will be repeatedly described only when necessary. Each embodiment in the following description exemplifies a device or a method for embodying the technical idea of this embodiment. Various modifications can be applied to one embodiment without departing from the scope of the disclosure. These embodiments and modification examples thereof are provided in the scope of the disclosure described in the claims and equivalents thereof.

In the drawings, in order to make the description clearer, the width, thickness, shape, and so on of each portion may be schematically represented as compared with the actual aspect, and yet this is only an example and does not limit the interpretation of the present disclosure. In this specification and the drawings, elements identical in function to those described with regard to the previous drawings are denoted by the same reference numerals and redundant description may be omitted.

In this specification, the expression that “α includes A, B, or C” does not exclude α including a plurality of combinations of A to C unless otherwise specified. Further, these expressions do not exclude a including another element.

In this specification, horizontal may refer to the direction (XY direction) that is parallel to the bottom surface of a substrate and vertical may refer to a direction (Z direction) that is substantially perpendicular to the horizontal direction.

Each of the following embodiments can be mutually combined insofar as there is no technical contradiction.

In each of the following embodiments, a template used for nanoimprint lithography will be described as an example of a substrate on which a pattern is formed, and yet the technique of the present disclosure is also applicable to non-template pattern formation. In addition, in each of the following embodiments, a method for manufacturing a semiconductor device using a template will be described as an example, and yet the technique of the present disclosure is also applicable to manufacturing methods for devices other than semiconductor devices.

### First Embodiment

### [Configuration of Template]

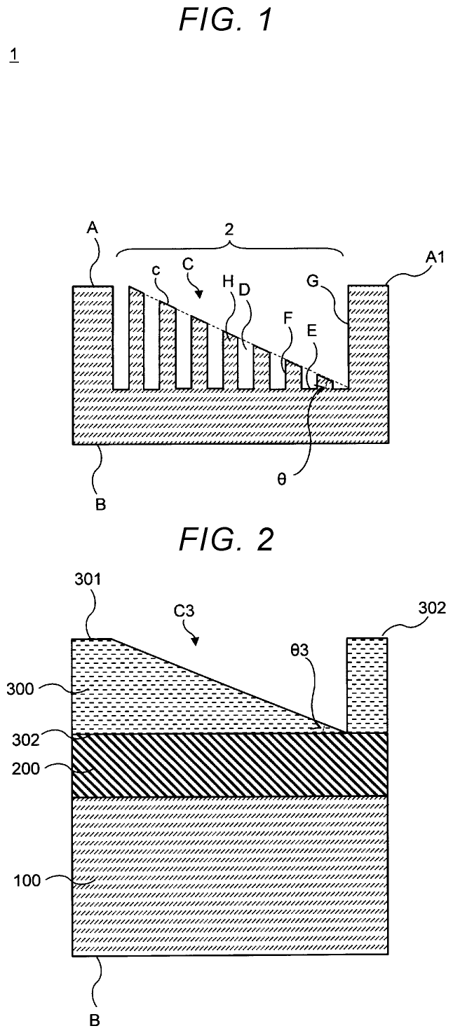

FIG. 1 is a cross-sectional view illustrating the configuration of a template 1. The template 1 has a pattern 2 on a first surface A. The pattern 2 is formed on the inner side with respect to an outer peripheral portion A1 of the first surface A. In other words, the outer peripheral portion A1 of the first surface A is substantially parallel to a second surface B on the side opposite to the first surface A. However, the pattern 2 is not limited thereto and may be formed in any region of the first surface A. The pattern 2 is preferably formed on the inner side with respect to any two sides of the outer peripheral portion A1. The material of the template 1 is, for example, quartz. However, the material of the template 1 is not limited thereto and may be, for example, silicon or the like.

### [Configuration of Pattern]

The pattern 2 includes a recess portion D in an inclined portion C. The inclined portion C has a virtual plane (dashed line) that intersects the first surface A and a bottom surface E of the recessed portion D. The virtual plane (dashed line) has a substantially planar shape. However, the virtual plane (dashed line) is not limited thereto and may intersect with a gently curved plane, may intersect with two or more planes, or may intersect with a combination of a plane and a curved plane from the first surface A to the bottom surface E of the recessed portion D. In the case of intersection with two or more planes, the planes may intersect at different angles and may have inclinations in opposite directions. The virtual plane (dashed line) may be positioned between the first surface A and the bottom surface E of the recessed portion D. The virtual plane (dashed line) of the inclined portion C and the bottom surface E of the recessed portion D may intersect at an acute angle. The bottom surface E and the first surface A are connected by a side wall G. The side wall G connects the bottom surface E and the first surface A substantially perpendicularly to the first surface A and the second surface B.

The inclined portion C includes the recessed portion D. The recessed portion D includes side surfaces F and the bottom surface E connecting the side surfaces F to each other. The side surface F of the recessed portion D connects an upper surface c substantially perpendicularly to the first surface A and the second surface B. The bottom surface E of the recessed portion D connects the side surfaces F of the recessed portion D to each other on a plane substantially parallel to the first surface A and the second surface B. In other words, the pattern 2 includes a plurality of protrusion portions H on the bottom surface E. The protrusion portion H includes the side surfaces F and the upper surface c connecting the side surfaces F to each other. The side surface F of the protrusion portion H connects the upper surface c substantially perpendicularly to the first surface A and the second surface B. The upper surface c of the protrusion portion H connects the side surfaces F of the protrusion portion H to each other along the virtual plane (dashed line). In other words, the upper surface c of the protrusion portion H is at the same height as the first surface A or lower than the first surface A.

The pattern 2 according to the present embodiment includes the plurality of protrusion portions H different in height (gradation) on the bottom surface E of the recessed portion D. In the illustration of FIG. 1, one recessed portion D is provided with seven protrusion portions H. However, the number of protrusion portions H is not particularly limited, and the pattern 2 may include two or more protrusion portions H different in height on the bottom surface E of the recessed portion D. The pattern 2 may have a region on the bottom surface E where the protrusion portion H is not disposed. Every protrusion portion H according to the present embodiment has a cylindrical column shape. However, the shape of the protrusion portion H is not particularly limited, and the protrusion portion H may have a prismatic shape or a wall shape. For example, the recessed portion D may be divided into a plurality of portions by the protrusion portion H that has a wall shape. In this case, the bottom surfaces E of the plurality of recessed portions D may be disposed on one plane substantially parallel to the first surface A and the second surface B. It should be noted that although FIG. 1 illustrates the protrusion portions H different in height in the left-right direction of the paper, the pattern 2 according to the present embodiment is also applicable in the depth direction of the paper.

### [Pattern Forming Method]

The template manufacturing method according to the present embodiment, particularly a template pattern forming method, will be described with reference to FIGS. 2 to 7. It should be noted that although FIGS. 2 to 7 illustrate an example of forming the protrusion portions H different in height in the left-right direction of the paper, the method for forming the pattern 2 according to the present embodiment is also applicable in the depth direction of the paper.

As illustrated in FIG. 2, a stacked body is prepared in which a first layer 100, a second layer 200, and a third layer 300 (first resin layer) are stacked in this order. Methods for manufacturing the stacked body are not particularly limited. The first layer 100, the second layer 200, and the third layer 300 are in contact with each other. In the present embodiment, quartz is exemplified as the material of the first layer 100. However, the material of the first layer 100 is not limited thereto and may be, for example, silicon. The second layer 200 may function as a hard mask, and the material of the second layer 200 may be, for example, a compound containing carbon or silicon. Alternatively, the material of the second layer 200 may be a metal compound containing chromium or tantalum. The third layer 300 may function as a resist, and the material of the third layer 300 may be, for example, a photosensitizer-containing resin.

An inclined portion C3 is formed on a surface 301, which is on the side opposite to the second layer 200, of the third layer 300, which is in contact with the second layer 200. Methods for forming the inclined portion C3 are not particularly limited. The inclined portion C3 may be formed by, for example, nanoimprint lithography, may be formed by applying a gradient to the amount of exposure by photolithography, or may be formed by applying a gradient to the amount of energy by laser irradiation. The inclined portion C3 is formed on the inner side with respect to an outer peripheral portion 302 of the surface 301. In other words, the outer peripheral portion 302 of the surface 301 is substantially parallel to the surface B of the first layer 100 on the side opposite to the second layer 200. However, the inclined portion C3 is not limited thereto and may be formed in any region of the surface 301. The inclined portion C3 is preferably formed on the inner side with respect to any two sides of the outer peripheral portion 302. In addition, the surface 301 of the third layer 300 may be formed with a structure other than the inclined portion C3. For example, the surface 301 of the third layer 300 may be combined with a recessed portion or the like that exposes the second layer 200.

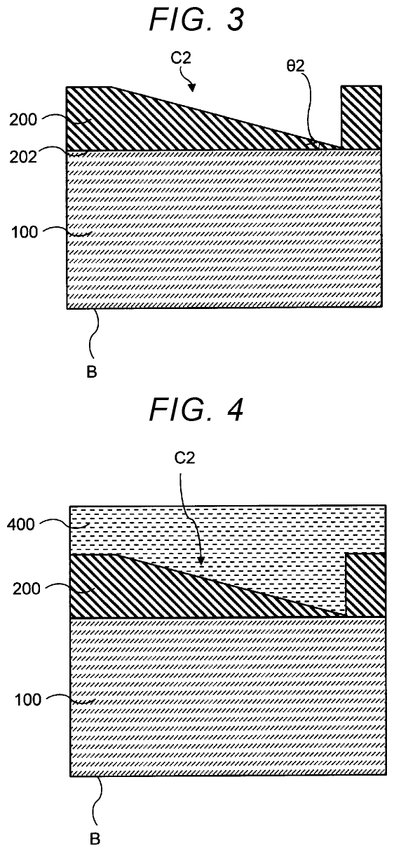

As illustrated in FIG. 3, the second layer 200 is processed using the third layer 300 including the inclined portion C3 as a mask. An inclined portion C2 determined by the processing speeds (etching rates) of the third layer 300 and the second layer 200 is transferred to the second layer 200. For example, if the third layer 300 is higher in processing speed than the second layer 200, an angle θ2 between a surface 202 of the second layer 200 in contact with the first layer 100 and the inclined portion C2 is smaller than an angle θ3 between the surface 302 of the third layer 300 in contact with the second layer 200 and the inclined portion C3. For example, if the second layer 200 is higher in processing speed than the third layer 300, the angle θ2 between the surface 202 of the second layer 200 and the inclined portion C2 is larger than the angle θ3 between the surface 302 of the third layer 300 and the inclined portion C3.

As illustrated in FIG. 4, a fourth layer 400 (second resin layer) is formed on the second layer 200 including the inclined portion C2 so as to fill the inclined portion C2. The fourth layer 400 may function as a resist, and the material of the fourth layer 400 may be, for example, a photosensitizer-containing resin.

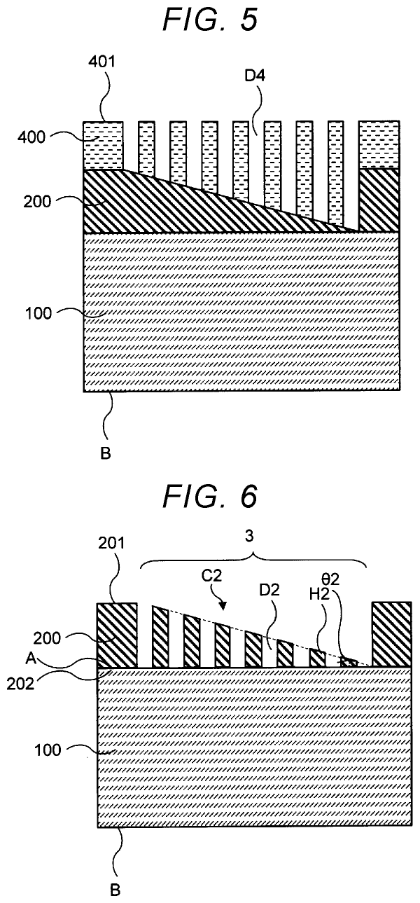

As illustrated in FIG. 5, a recessed portion D4 is formed in a surface 401, which is on the side opposite to the second layer 200, of the fourth layer 400, which is in contact with the second layer 200. The recessed portion D4 is formed on the inclined portion C2 using the inclined portion C2 of the second layer 200 as a stopper. The recessed portion D4 exposes the inclined portion C2 of the second layer 200. Methods for forming the recessed portion D4 are not particularly limited. The recessed portion D4 may be formed by, for example, photolithography using a mask having the upper surface pattern of the recessed portion D4.

As illustrated in FIG. 6, the second layer 200 is processed using the fourth layer 400 including the recessed portion D4 as a mask. A recessed portion D2 is transferred to the inclined portion C2 of the second layer 200 using the surface A on the side opposite to the surface B of the first layer 100 as a stopper, and a pattern 3 including the recessed portion D2 is formed in the inclined portion C2. The recessed portion D2 exposes the surface A of the first layer 100 at the bottom portion of the recessed portion D2. The thickness of the fourth layer 400 is appropriately set depending on the processing speeds of the fourth layer 400 and the second layer 200 and the thickness of the second layer 200. After that, the remaining fourth layer 400 is peeled off. By the pattern forming method according to the present embodiment, it is possible to form the pattern 3 having protrusion portions H2 different in height on the surface A of the first layer 100 by forming the recessed portion D2 in the inclined portion C2 of the second layer 200.

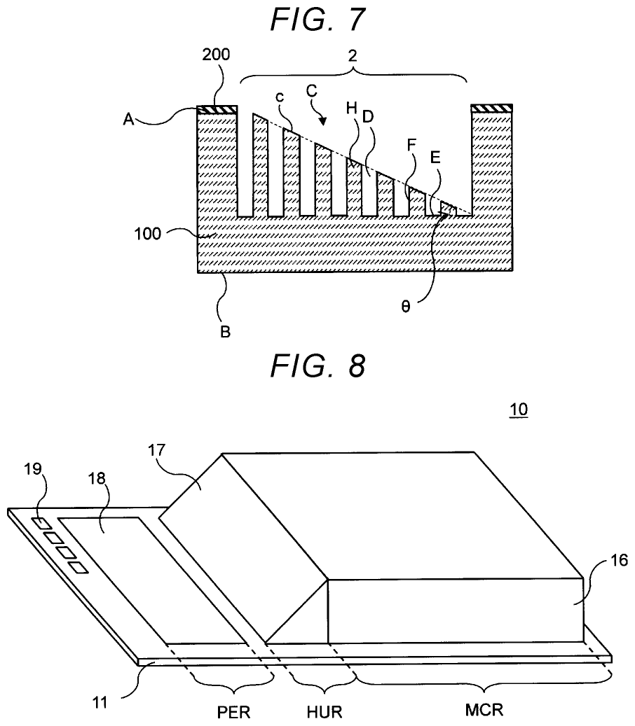

As illustrated in FIG. 7, the first layer 100 is processed (first etching) using the second layer 200 including the pattern 3 as a mask. The first layer 100 exposed by the recessed portion D2 of the pattern 3 is etched by the first etching. At this time, the second layer 200 is also reduced by the first etching. The first etching may be, for example, RIE using a fluorine-based reaction gas.

The pattern 2 including the recessed portion D in the inclined portion C determined by the processing speeds of the first layer 100 and the second layer 200 is transferred to the surface A of the first layer 100. For example, if the first layer 100 is higher in processing speed than the second layer 200, an angle θ between the bottom surface E of the recessed portion D and the inclined portion C is larger than the angle θ2 between the surface 202 of the second layer 200 and the inclined portion C2, and the depth of the recessed portion D from the surface A to the bottom surface E is larger than the depth of the recessed portion D2 from a surface 201 to the surface 202. In other words, it is possible to form the pattern 2, which is equivalent to the pattern 3 expanded in the stacking direction and has the protrusion portions H different in height on the bottom surface E. The thickness of the second layer 200 and the angle θ2 between the surface 202 of the second layer 200 and the inclined portion C2 (gradation count of the pattern 3) are appropriately set depending on, for example, the processing speeds of the first layer 100 and the second layer 200 in the first etching, the disposition of the recessed portion D or the protrusion portion H of the pattern 2, the angle θ between the bottom surface E of the recessed portion D and the inclined portion C (gradation count of the pattern 2), the height from the bottom surface E to the surface A (height of the pattern 2), the depth of the recessed portion D from the surface A to the bottom surface E (depth of the pattern 2), and the accuracy of control of the processing amount of the first layer 100 in the first etching. After that, it is possible to manufacture the template 1 illustrated in FIG. 1 by peeling off the remaining second layer 200.

By the template manufacturing method according to the present embodiment, it is possible to improve the formation efficiency and accuracy of the pattern 2 including the plurality of protrusion portions H different in height (gradation) on the bottom surface E of the recessed portion D.

### [Overall Configuration of Semiconductor Device]

An overall configuration of the semiconductor device according to the present embodiment will be described with reference to FIG. 8. FIG. 8 is a perspective view illustrating the disposition of each element of a semiconductor device 10 according to the present embodiment.

The semiconductor device 10 is a NAND flash memory device and is formed on a semiconductor substrate 11. A memory cell region MCR and a contact region HUR are defined on the semiconductor substrate 11. A memory cell array 16 including a plurality of three-dimensionally stacked memory cells is formed in the memory cell region MCR. Specifically, a source-side select gate transistor, multiple (for example, 64) memory cell transistors, and a drain-side select gate transistor are connected in series in the direction perpendicular to the surface of the semiconductor substrate 11 to configure a memory string. It should be noted that dummy cell transistors may be included at both ends of the multiple memory cell transistors connected in series or at a part between the multiple memory cell transistors. The memory cell array 16 includes a stacked body in which a plurality of conductive layers, which are source-side select gate lines, word lines, and drain-side select gate lines connected to the respective transistors, are stacked via insulating layers. The plurality of conductive layers extend to the contact region HUR to form a stacked wiring structure 17. Bit lines (not illustrated) are provided on the memory cell array 16 and connected to a peripheral circuit 18. Wiring (not illustrated) is provided on the stacked wiring structure 17 and connected to the peripheral circuit 18.

A peripheral circuit region PER is further defined on the semiconductor substrate 11. The peripheral circuit 18 is formed in the peripheral circuit region PER. The peripheral circuit 18 has multiple CMOS transistors. The peripheral circuit 18 has, for example, a column circuit including a drive circuit driving each word line connected to a memory cell, a decoder circuit selecting each word line, a sense amplifier sensing the bit line potential during reading, and a bit line potential control circuit supplying voltage to the bit line during writing. It should be noted that the wiring of the peripheral circuit region PER is omitted in FIG. 8. The semiconductor substrate 11 has a pad column 19 for exchanging signals with the outside of the chip and receiving power supply.

### [Configurations of Memory Cell Region MCR and Contact Region HUR]

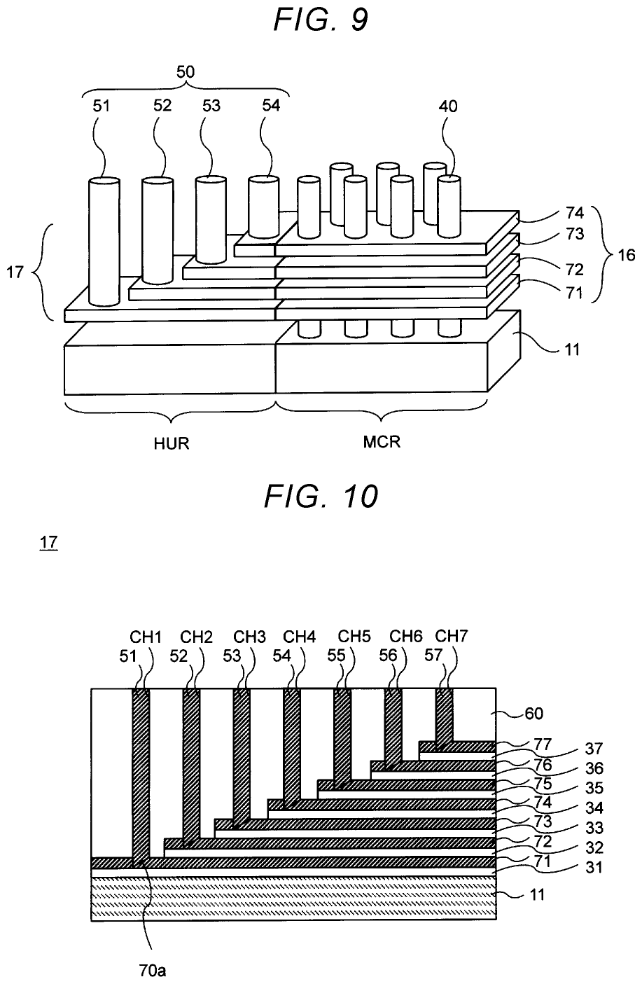

FIG. 9 is a perspective view illustrating the configurations of the memory cell region MCR and the contact region HUR of the semiconductor device according to the present embodiment. In order to avoid complication of the drawings, conductive members are illustrated with insulating members omitted. Parts in FIG. 9 where members are not illustrated are insulated using an insulating material such as silicon dioxide.

In the memory cell region MCR, the memory cell array 16 is formed on the semiconductor substrate 11 using a silicon single crystal. The memory cell array 16 has conductive layers 71, 72, 73, and 74 extending substantially parallel to the surface of the semiconductor substrate 11 (the conductive layers 71 to 74 will be referred to as conductive layers 70 when not distinguished). The memory cell array 16 has a stacked body in which the plurality of conductive layers 70 are stacked via insulating layers. Although only four conductive layers are illustrated in the drawing, a larger number of layers such as 33 layers and 65 layers are stacked. These conductive layers correspond to source-side select gate lines, word lines, or drain-side select gate lines connected to transistors.

Memory pillars 40 penetrating the plurality of conductive layers and the plurality of insulating layers are formed in the memory cell region MCR. The memory pillar has a cylindrical shape, and a block insulating film including a silicon dioxide film, a charge storage film including a silicon nitride film, a tunnel insulating film including a silicon dioxide film, a semiconductor channel including an amorphous or polycrystalline silicon film, and a silicon dioxide film are stacked from the outer peripheral side toward the center side. A part of the charge storage film positioned between the semiconductor channel and the conductive layers 71, 72, 73, and 74 corresponding to the select gate line or word line functions as a part of a carrier-trapping nonvolatile memory cell.

In the contact region HUR, the stacked wiring structure 17 is formed on the semiconductor substrate 11 using a silicon single crystal. A plurality of conductive layers and a plurality of insulating layers extending from the memory cell region MCR are also formed in the contact region HUR. The stacked wiring structure 17 has the conductive layer 71, the conductive layer 72, the conductive layer 73, and the conductive layer 74 extending substantially parallel to the surface of the semiconductor substrate 11. The stacked wiring structure 17 has a stacked body in which the plurality of conductive layers 70 are stacked via insulating layers. Although only four conductive layers are illustrated in the drawing, as described above, a larger number of layers such as 33 layers and 65 layers are stacked. Further, in the contact region HUR, the plurality of conductive layers 70 correspond to wiring led out from source-side select gate lines, word lines, or drain-side select gate lines.

In the contact region HUR, the conductive layers 71, 72, 73, and 74 corresponding to wiring led out from select gate lines or word lines are formed in a stepped structure so as to expose a part of the lower conductive layer. The conductive layers 71, 72, 73, and 74 are respectively connected to corresponding contact plugs 51, 52, 53, and 54 in regions exposed in the stepped structure (here, the contact plugs 51 to 54 will be referred to as contact plugs when not distinguished). Here, the conductive layer 71 is connected to the contact plug 51, the conductive layer 72 is connected to the contact plug 52, the conductive layer 73 is connected to the contact plug 53, and the conductive layer 74 is connected to the contact plug 54. Although only four contact plugs 50 are illustrated in the drawing, the contact plugs 50 that are equal in number to, for example, the plurality of conductive layers are disposed. Each contact plug 50 is led out onto the stacked wiring structure 17 via a contact hole penetrating an insulator (not illustrated).

### [Configuration of Stacked Wiring Structure]

FIG. 10 is a cross-sectional view illustrating the configuration of the stacked wiring structure 17. The stacked wiring structure 17 has an insulating layer 31, the conductive layer 71, an insulating layer 32, the conductive layer 72, an insulating layer 33, the conductive layer 73, an insulating layer 34, the conductive layer 74, an insulating layer 35, a conductive layer 75, an insulating layer 36, a conductive layer 76, an insulating layer 37, and a conductive layer 77 stacked on the semiconductor substrate 11 (here, the conductive layers 71 to 77 will be referred to as the conductive layers 70 when not distinguished, and the insulating layers 31 to 37 will be referred to as insulating layers 30 when not distinguished). The plurality of conductive layers 70 and the plurality of insulating layers 30 are stacked alternately, periodically, and layer by layer in the direction (stacking direction) perpendicular to the main surface of the semiconductor substrate 11. The insulating layer 31 is also formed between the semiconductor substrate 11 and the lowermost conductive layer 71. An insulator 60 is formed on the uppermost conductive layer 77. The insulator 60 may be thicker in the stacking direction than the insulating layers 31 to 37.

Each conductive layer 70 is a single layer. In other words, in a case where the cross-sectional shape of one conductive layer 70 is observed, a single material may be continuous in the film thickness direction of the conductive layer 70 (Z direction). In addition, no interface may be present in one conductive layer 70. Alternatively, the conductive layer 70 may be the two layers of a barrier metal layer and a metal layer. The material of the conductive layer 70 may be, for example, tungsten. The barrier metal layer may be, for example, titanium nitride (TiN) or tantalum nitride (TaN). The conductive layers 70 adjacent in the stacking direction may be mutually insulated, and the material of the insulating layer 30 may be, for example, silicon oxide such as silicon dioxide (SiO₂) and tetra ethyl ortho silicate (TEOS). The insulating layer 30 is deposited using, for example, a chemical vapor deposition (CVD) apparatus.

Each of the plurality of conductive layers 70 and the plurality of insulating layers 30 is formed in a stepped structure so as to expose a part of the lower conductive layer 70. The insulator 60 embedding the stepped structure is formed on the stepped structure of the stacked body. The material of the insulator 60 may be, for example, silicon oxide such as silicon dioxide (SiO₂) and tetra ethyl ortho silicate (TEOS).

A plurality of contact holes CH1, CH2, CH3, CH4, CH5, CH6, and CH7 are formed in the insulator 60 to expose a part of the conductive layers 71 to 77 (here, the contact holes CH1 to CH7 will be referred to as contact holes CH when not distinguished). The contact hole CH penetrates the insulator 60 up to the corresponding conductive layer 70. The contact hole CH exposes the conductive layer 70 corresponding in the stepped structure at the bottom portion. In other words, the contact holes CH are different in depth from the upper surface of the semiconductor device.

The contact plugs 51, 52, 53, 54, 55, 56, and 57 are formed in the contact holes CH1 to CH7 (here, the contact plugs 51 to 57 will be referred to as the contact plugs 50 when not distinguished). The contact plug 50 is connected to the corresponding conductive layer 70 at the bottom portion of the contact hole CH. Each contact plug 50 is led out onto the stacked wiring structure 17 (side opposite to the substrate 11) via the contact hole CH penetrating the insulator 60 disposed on the corresponding conductive layer 70. Specifically, the contact plug 51 is connected to the conductive layer 71 via the contact hole CH1, the contact plug 52 is connected to the conductive layer 72 via the contact hole CH2, the contact plug 53 is connected to the conductive layer 73 via the contact hole CH3, the contact plug 54 is connected to the conductive layer 74 via the contact hole CH4, the contact plug 55 is connected to the conductive layer 75 via the contact hole CH5, the contact plug 56 is connected to the conductive layer 76 via the contact hole CH6, and the contact plug 57 is connected to the conductive layer 77 via the contact hole CH7. In other words, the contact holes CH and the contact plugs 50 are different in length from the upper surface of the insulator 60. Although every contact plug 50 has a cylindrical column shape, the shapes of the contact plugs 50 are not particularly limited. The material of the contact plug 50 may be, for example, a metal such as tungsten.

The contact region of the conductive layer 70 where the contact plug 50 is connected may have a boundary 70a corresponding to the shape of the tip of a template forming the contact hole CH. The boundary 70a may be disposed in the middle of each conductive layer 70 (between the upper and lower surfaces). The contact plugs 50 are connected at the boundaries 70a of the conductive layers 70, respectively.

In the stacked wiring structure of the semiconductor device according to the present embodiment, the contact plug 50 is connected at the boundary 70a of the conductive layer 70, and thus the contact area between the contact plug 50 and the conductive layer 70 can be increased and the reliability of the semiconductor device can be further improved.

### [Method for Manufacturing Stacked Wiring Structure]

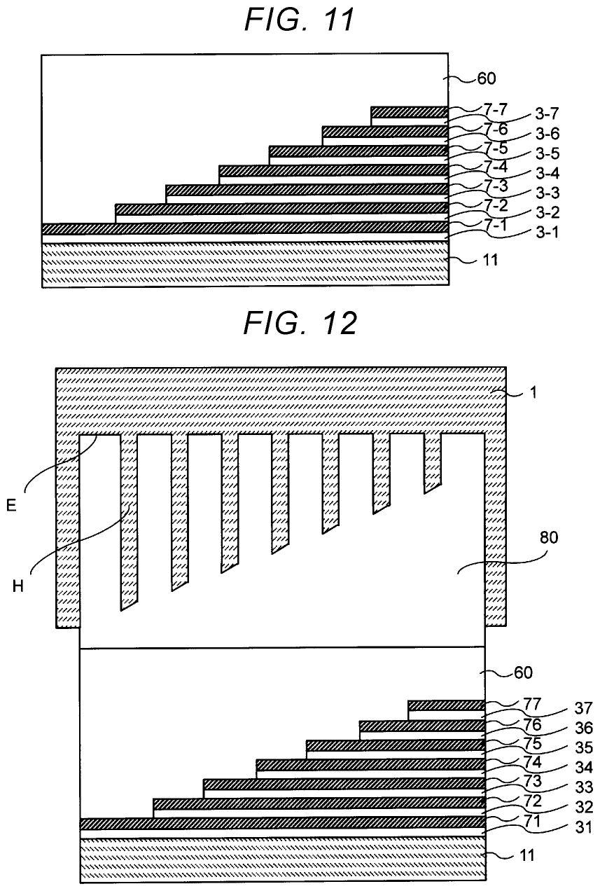

A method for manufacturing the stacked wiring structure of the semiconductor device according to the present embodiment, particularly a stacked wiring structure pattern forming method, will be described with reference to FIGS. 11 to 14. It should be noted that although FIGS. 11 to 14 illustrate an example of forming the contact holes CH and the contact plugs 50 different in depth in the left-right direction of the paper, the method for manufacturing the stacked wiring structure of the semiconductor device according to the present embodiment is also applicable in the depth direction of the paper.

As illustrated in FIG. 11, a stacked body is prepared in which the insulating layer 31, the conductive layer 71, the insulating layer 32, the conductive layer 72, the insulating layer 33, the conductive layer 73, the insulating layer 34, the conductive layer 74, the insulating layer 35, the conductive layer 75, the insulating layer 36, the conductive layer 76, the insulating layer 37, and the conductive layer 77 are formed in order on the semiconductor substrate 11. Methods for manufacturing the stacked body are not particularly limited. The alternately stacked insulating layers 30 and conductive layers 70 are in contact with each other. Each of the plurality of conductive layers 70 and the plurality of insulating layers 30 is formed in a stepped structure so as to expose a part of the lower conductive layer 70. The contact plug 50 to be described later is connected to the contact region where the conductive layer 70 is exposed in the stepped structure. In the present embodiment, a TEOS film is exemplified as the material of the insulating layer 30, and yet the material of the insulating layer 30 is not limited thereto and may be, for example, silicon dioxide (SiO₂). Although tungsten is exemplified as the material of the conductive layer 70, the conductive layer 70 is not limited thereto. For example, the conductive layer 70 may be a sacrifice layer preceding replacement with a conductive layer in a known semiconductor device manufacturing method or may be a silicon nitride film (SiN) or silicon. In the present embodiment, a configuration with a stepped structure is exemplified as the stacked body, and yet the stacked body is not limited thereto. The stacked body may have a power contact structure in which the insulating layers 30 and the conductive layers 70 of approximately the same size are alternately stacked in the horizontal rear of the semiconductor substrate 11, and the conductive layer 70 may be a sacrifice layer preceding replacement with a conductive layer. In this case, the stacked body is processed together with the insulator 60 to be described later and the contact plug 50 penetrates the conductive layer 70.

The insulator 60 is formed on the stacked body so as to cover the stepped structure of the stacked body. The material of the insulator 60 may be, for example, silicon oxide.

As illustrated in FIG. 12, an insulator 80 is applied onto the insulator 60. The material of the insulator 80 is, for example, a resist and may be a thermosetting resin or a photocurable resin. In addition, a film such as a hard mask may be formed between the insulator 60 and the insulator 80. The pattern of the contact holes CH1, CH2, CH3, CH4, CH5, CH6, and CH7 is formed in the applied insulator 80 by nanoimprint lithography. The upper surface of the insulator 80 is partially flattened and partially patterned by nanoimprint lithography. For the nanoimprint lithography, the template 1 is used in which the bottom surface E is flat and the plurality of protrusion portions H different in height (gradation) are provided on the bottom surface E. The plurality of protrusion portions H of the template 1 are different in height (gradation) with the sum of the stacking-direction thicknesses of each insulating layer 30 and each conductive layer 70 being one unit. By using the template 1 to imprint on the insulator 80, the upper surface of the insulator 80 is flattened and the pattern of the plurality of contact holes CH different in depth is formed. Preferably, the template 1 is used to imprint such that the surface B of the template 1 (surface on the side opposite to the surface having the protrusion portion) and the low surface of the semiconductor substrate 11 (surface on the side opposite to the surface having the stacked body) are substantially parallel. The insulator 80 imprinted with the pattern of the contact holes CH may be cured by, for example, UV irradiation.

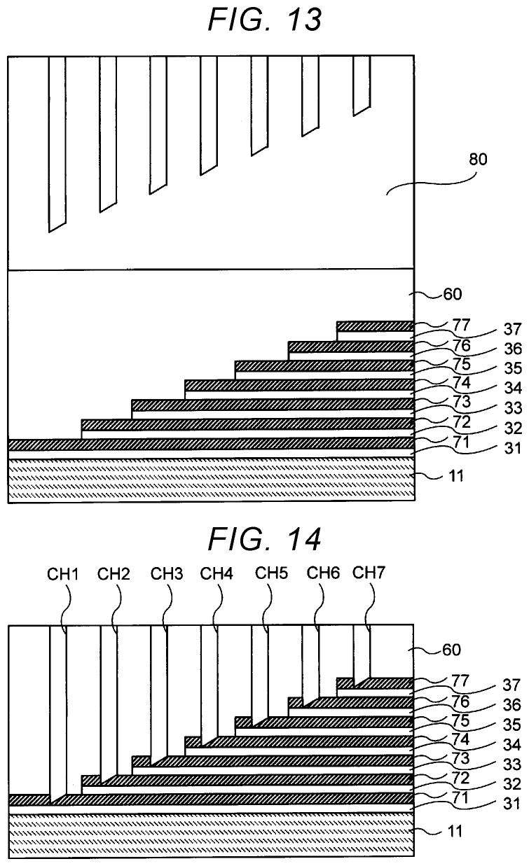

As illustrated in FIG. 13, by releasing the template 1, the upper surface of the insulator 80 is flattened and the pattern of the plurality of contact holes CH different in depth is formed.

As illustrated in FIG. 14, the insulator 60 is processed using the insulator 80 including the pattern of the plurality of contact holes CH different in depth as a mask. The insulator 80 and the insulator 60 may be removed in part by, for example, anisotropic etching such as reactive ion etching (RIE). The pattern of the plurality of contact holes CH different in depth of the insulator 80 is transferred to the insulator 60. The formed contact holes CH1, CH2, CH3, CH4, CH5, CH6, and CH7 are different in depth from the upper surface of the insulator 60. The conductive layer 70 is exposed at the bottom portion (contact region) of the contact hole CH. At this time, along with the processing of the insulators 80 and 60, the conductive layer 70 may also be removed in part. A pattern (recessed portion) corresponding to the shape of the tip of the template forming the contact hole CH may be formed on the conductive layer 70 in the contact region. However, the conductive layer 70 is not limited thereto, and the conductive layer 70 may function as a stopper and expose the flat upper surface of the conductive layer 70.

The contact plug 50 illustrated in FIG. 10 is formed by embedding a metal (conductor) such as tungsten in the contact hole CH exposing the conductive layer 70 corresponding to the bottom portion.

In the method for manufacturing the stacked wiring structure of the semiconductor device according to the present embodiment, the contact holes CH different in depth (gradation) can be patterned at once in the insulator 60 by nanoimprint lithography using the template 1 according to the present embodiment, and manufacturing efficiency and accuracy can be improved. Since the template 1 according to the present embodiment has the upper surface c of the protrusion portion H along the virtual plane (dashed line), stress decreases and alignment becomes easier when the template 1 is used to imprint. Since the template 1 according to the present embodiment has the upper surface c of the protrusion portion H along the virtual plane (dashed line), a pattern (recessed portion) corresponding to the contact region of the conductive layer 70 can be formed, the contact area can be increased by fitting the contact plug 50, and the reliability and yield of the semiconductor device can be further improved.

### Second Embodiment

The configuration of the template according to the present embodiment is the same as the configuration of the template according to the first embodiment except for the shape of the upper surface of the protrusion portion of the pattern. The template pattern forming method according to the present embodiment is the same as the template pattern forming method according to the first embodiment up to the formation of the pattern 3 including the recessed portion D2 in the inclined portion C2 on the second layer 200. The configuration of the stacked wiring structure according to the present embodiment is the same as the configuration of the stacked wiring structure according to the first embodiment except for the shape of the contact portion between the contact plug and the conductive layer. The stacked wiring structure manufacturing method according to the present embodiment is the same as the stacked wiring structure manufacturing method according to the first embodiment except for the shape of the contact portion between the contact plug and the conductive layer. Descriptions that are the same as in the first embodiment are omitted, and differences from the first embodiment will be described here.

### [Configuration of Pattern]

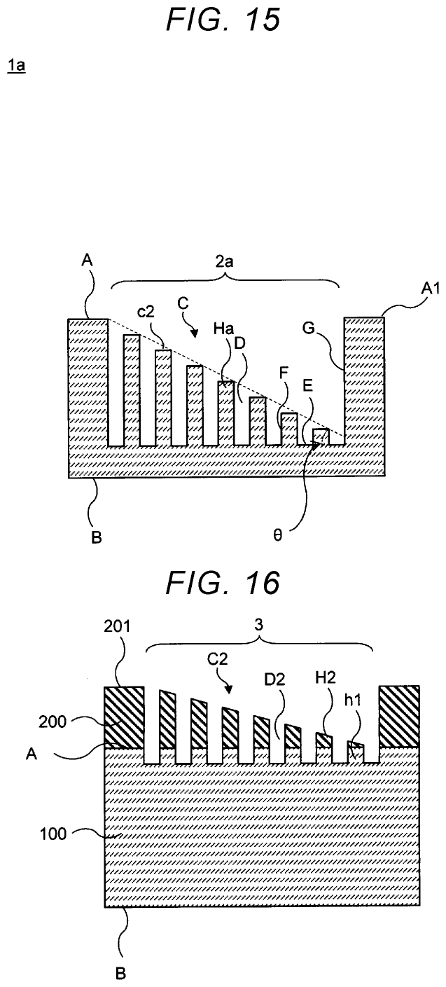

FIG. 15 is a cross-sectional view illustrating the configuration of a template 1a. The template 1a has a pattern 2a on the first surface A. The pattern 2a includes the recessed portion D in the inclined portion C. The inclined portion C has a virtual plane (dashed line) that intersects the first surface A and the bottom surface E of the recessed portion D. The virtual plane (dashed line) has a substantially planar shape. The virtual plane (dashed line) of the inclined portion C and the bottom surface E of the recessed portion D may intersect at an acute angle. The bottom surface E and the first surface A are connected by the side wall G. The side wall G connects the bottom surface E and the first surface A substantially perpendicularly to the first surface A and the second surface B.

The inclined portion C includes the recessed portion D. The recessed portion D includes the side surfaces F and the bottom surface E connecting the side surfaces F to each other. The side surface F of the recessed portion D connects an upper surface c2 substantially perpendicularly to the first surface A and the second surface B. The bottom surface E of the recessed portion D connects the side surfaces F of the recessed portion D to each other on a plane substantially parallel to the first surface A and the second surface B. In other words, the pattern 2a includes a plurality of protrusion portions Ha on the bottom surface E. The protrusion portion Ha includes the side surfaces F and the upper surface c2 connecting the side surfaces F to each other. The side surface F of the protrusion portion Ha connects the upper surface c2 substantially perpendicularly to the first surface A and the second surface B. At least a part of the upper surface c2 of the protrusion portion Ha is disposed along the virtual plane (dashed line). In other words, the upper surface c2 of the protrusion portion H is at the same height as the first surface A or lower than the first surface A.

### [Pattern Forming Method]

The template manufacturing method according to the present embodiment, particularly a template pattern forming method, will be described with reference to FIGS. 16 to 20.

The template pattern forming method according to the present embodiment is the same as the template pattern forming method according to the first embodiment (FIGS. 2 to 6) up to the formation of the pattern 3 including the recessed portion D2 in the inclined portion C2 on the second layer 200, and thus redundant description is omitted here.

As illustrated in FIG. 16, processing (first etching) is performed to partially remove the first layer 100 using the second layer 200 including the pattern 3 as a mask. The first layer 100 exposed by the recessed portion D2 of the pattern 3 is etched by the first etching. At this time, the second layer 200 is also reduced by the first etching. The first etching may be, for example, RIE using a fluorine-based reaction gas. The first etching is stopped before the lowest protrusion portion H2 in the inclined portion C2 is removed and the first layer 100 is exposed by the first etching. In other words, the first etching is stopped before the thinnest second layer 200 is removed and the first layer 100 is exposed by the first etching.

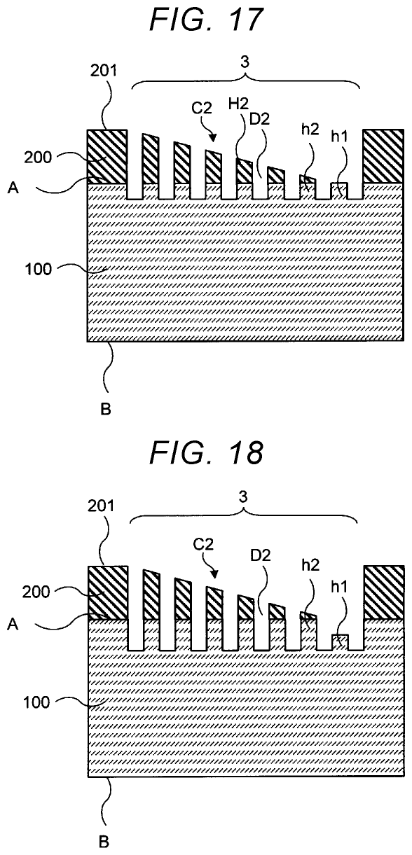

As illustrated in FIG. 17, processing (second etching) is performed to partially remove the second layer 200 including the pattern 3 using the first layer 100 as a stopper. The second etching may be, for example, RIE using a chlorine-based reaction gas. By the second etching, the lowest protrusion portion H2 in the inclined portion C2 is removed and the first surface A of the first layer 100 is exposed. In other words, by the second etching, the thinnest second layer 200 is removed and the first surface A of the first layer 100 is exposed. After the second layer 200 is removed, a protrusion portion h1 of the first layer 100 is formed.

As illustrated in FIG. 18, using the remaining second layer 200 including a part of the pattern 3 as a mask, the processing (first etching) is performed again to partially remove the first layer 100. The first layer 100 exposed by the recessed portion D2 of the pattern 3 is etched by the first etching. The protrusion portion h1 after the removal of the second layer 200 is also etched substantially parallel to the first surface A by the first etching. At this time, the second layer 200 is also reduced by the first etching. The first etching is stopped before the second-lowest protrusion portion H2 in the inclined portion C2 is removed and the first layer 100 is exposed by the first etching. In other words, the first etching is stopped before the second-thinnest second layer 200 is removed and the first layer 100 is exposed by the first etching.

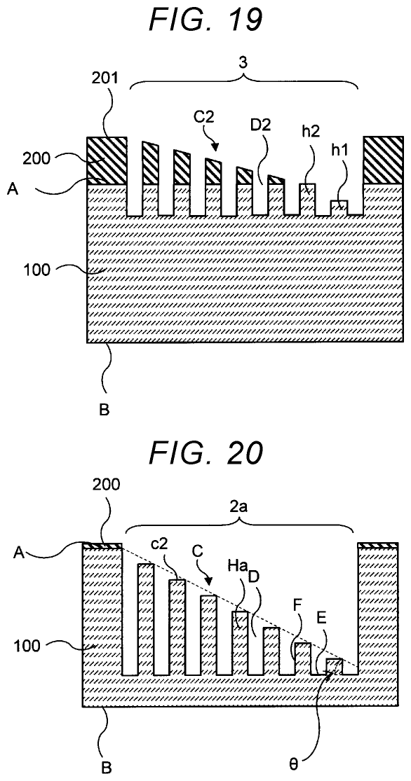

As illustrated in FIG. 19, processing (second etching) is performed to partially remove the remaining second layer 200 including a part of the pattern 3. By the second etching, the second-lowest protrusion portion H2 in the inclined portion C2 is removed and the first surface A of the first layer 100 is exposed. In other words, by the second etching, the second-thinnest second layer 200 is removed and the first surface A of the first layer 100 is exposed. After the second layer 200 is removed, a protrusion portion h2 of the first layer 100 is formed.

As illustrated in FIG. 20, by repeating the first etching and the second etching by the gradation count of the pattern 3, the pattern 2a including the recessed portion D in the inclined portion C determined by the processing speeds of the first layer 100 and the second layer 200 is transferred to the surface A of the first layer 100. For example, if the first layer 100 is higher in processing speed than the second layer 200, the angle θ between the bottom surface E of the recessed portion D and the inclined portion C is larger than the angle θ2 between the surface 202 of the second layer 200 and the inclined portion C2, and the depth of the recessed portion D from the surface A to the bottom surface E is larger than the depth of the recessed portion D2 from the surface 201 to the surface 202. In other words, it is possible to form the pattern 2a, which is equivalent to the pattern 3 expanded in the stacking direction and has the protrusion portions Ha different in height on the bottom surface E. The thickness of the second layer 200 and the angle θ2 between the surface 202 of the second layer 200 and the inclined portion C2 (gradation count of the pattern 3) are appropriately set depending on, for example, the processing speeds of the first layer 100 and the second layer 200 in the first etching, the disposition of the recessed portion D or the protrusion portion Ha of the pattern 2a, the angle θ between the bottom surface E of the recessed portion D and the inclined portion C (gradation count of the pattern 2a), the height from the bottom surface E to the surface A (height of the pattern 2a), the depth of the recessed portion D from the surface A to the bottom surface E (depth of the pattern 2a), the accuracy of control of the processing amount of the first layer 100 in the first etching, the processing speeds of the first layer 100 and the second layer 200 in the second etching, and the processing amount buffer of the second layer 200 in the second etching. After that, it is possible to manufacture the template 1a illustrated in FIG. 15 by peeling off the remaining second layer 200.

By the template manufacturing method according to the present embodiment, it is possible to improve the formation efficiency and accuracy of the pattern 2a including the plurality of protrusion portions Ha different in height (gradation) on the bottom surface E of the recessed portion D.

### [Configuration of Stacked Wiring Structure]

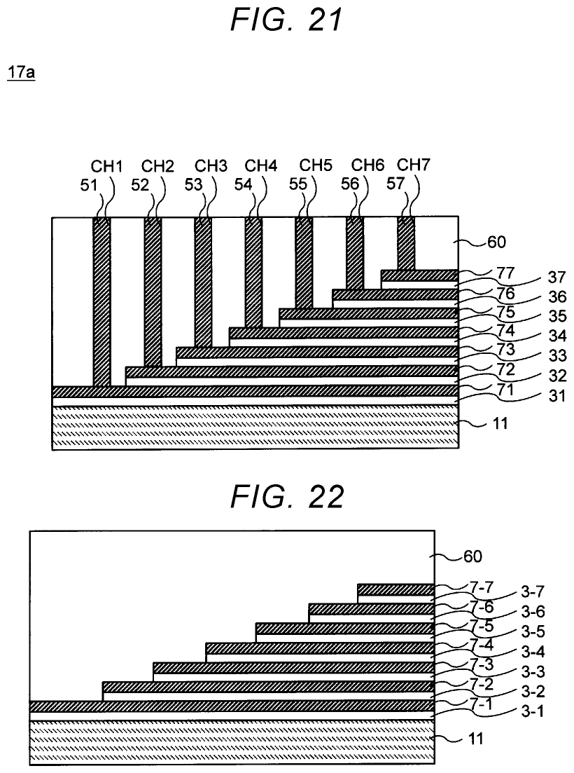

FIG. 21 is a cross-sectional view illustrating the configuration of a stacked wiring structure. The configuration of the stacked wiring structure according to the present embodiment is the same as the configuration of the stacked wiring structure according to the first embodiment except for the shape of the contact portion between the contact plug and the conductive layer, and thus redundant description is omitted here.

The stacked wiring structure 17 has the plurality of conductive layers 70 and the plurality of insulating layers 30 stacked on the semiconductor substrate 11. The plurality of conductive layers 70 and the plurality of insulating layers 30 are stacked alternately, periodically, and layer by layer in the direction (stacking direction) perpendicular to the main surface of the semiconductor substrate 11. The insulating layer 31 is also formed between the semiconductor substrate 11 and the lowermost conductive layer 71. The insulator 60 is formed on the uppermost conductive layer 77. Each of the plurality of conductive layers 70 and the plurality of insulating layers 30 is formed in a stepped structure so as to expose a part of the lower conductive layer 70. The insulator 60 embedding the stepped structure is formed on the stepped structure of the stacked body.

The plurality of contact holes CH are formed in the insulator 60 to expose a part of the conductive layers 71 to 77. The contact hole CH penetrates the insulator 60 up to the corresponding conductive layer 70. The contact hole CH exposes the corresponding conductive layer 70 in the stepped structure at the bottom portion. In other words, the contact holes CH are different in depth from the upper surface of the semiconductor device.

The contact plugs 50 are formed in the contact holes CH. The contact plug 50 is connected to the corresponding conductive layer 70 at the bottom portion of the contact hole CH. Each contact plug 50 is led out onto the stacked wiring structure 17 (side opposite to the substrate 11) via the contact hole CH penetrating the insulator 60 disposed on the corresponding conductive layer 70. The contact holes CH and the contact plugs 50 are different in length from the upper surface of the insulator 60. The contact plug is connected to the contact region of the conductive layer 70. The contact plugs 50 are connected to the upper surfaces of the conductive layers 70, respectively.

In the stacked wiring structure of the semiconductor device according to the present embodiment, the contact plug 50 is connected to the upper surface of the conductive layer 70, and thus the reliability of the semiconductor device can be improved.

### [Method for Manufacturing Stacked Wiring Structure]

A method for manufacturing the stacked wiring structure of the semiconductor device according to the present embodiment, particularly a stacked wiring structure pattern forming method, will be described with reference to FIGS. 22 to 25. The stacked wiring structure manufacturing method according to the present embodiment is the same as the configuration of the stacked wiring structure according to the first embodiment except for the shape of the contact portion between the contact plug and the conductive layer, and thus redundant description is omitted here.

As illustrated in FIG. 22, a stacked body is prepared in which the conductive layers 70 and the insulating layers 30 are alternately formed on the semiconductor substrate 11. The alternately stacked insulating layers 30 and conductive layers 70 are in contact with each other. Each of the plurality of conductive layers 70 and the plurality of insulating layers 30 is formed in a stepped structure so as to expose a part of the lower conductive layer 70. The contact plug 50 to be described later is connected to the contact region where the conductive layer 70 is exposed in the stepped structure. The insulator 60 is formed on the stacked body so as to cover the stepped structure of the stacked body.

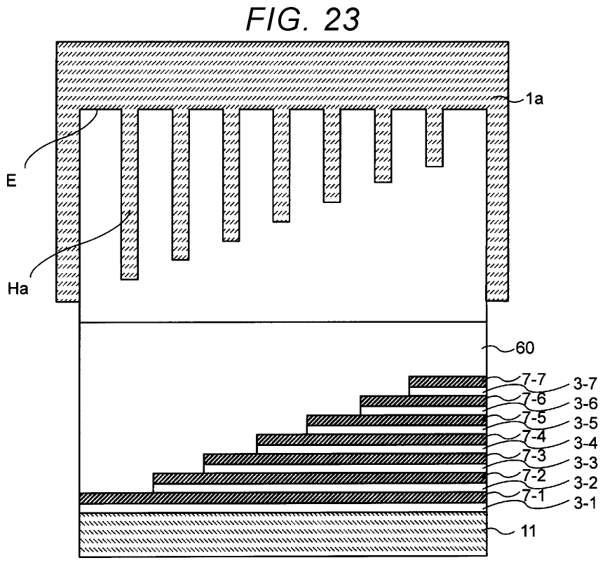

As illustrated in FIG. 23, the insulator 80 is applied onto the insulator 60. The pattern of the contact holes CH1, CH2, CH3, CH4, CH5, CH6, and CH7 is formed in the applied insulator 80 by nanoimprint lithography. The upper surface of the insulator 80 is partially flattened and partially patterned by nanoimprint lithography. For the nanoimprint lithography, the template 1a is used in which the bottom surface E is flat and the plurality of protrusion portions Ha different in height (gradation) are provided on the bottom surface E. The plurality of protrusion portions Ha of the template 1a are different in height (gradation) with the sum of the stacking-direction thicknesses of each insulating layer 30 and each conductive layer 70 being one unit. By using the template 1a to imprint on the insulator 80, the upper surface of the insulator 80 is flattened and the pattern of the plurality of contact holes CH different in depth is formed. Preferably, the template 1a is used to imprint such that the surface B of the template 1a (surface on the side opposite to the surface having the protrusion portion) and the low surface of the semiconductor substrate 11 (surface on the side opposite to the surface having the stacked body) are substantially parallel. The insulator 80 imprinted with the pattern of the contact holes CH may be cured by, for example, UV irradiation.

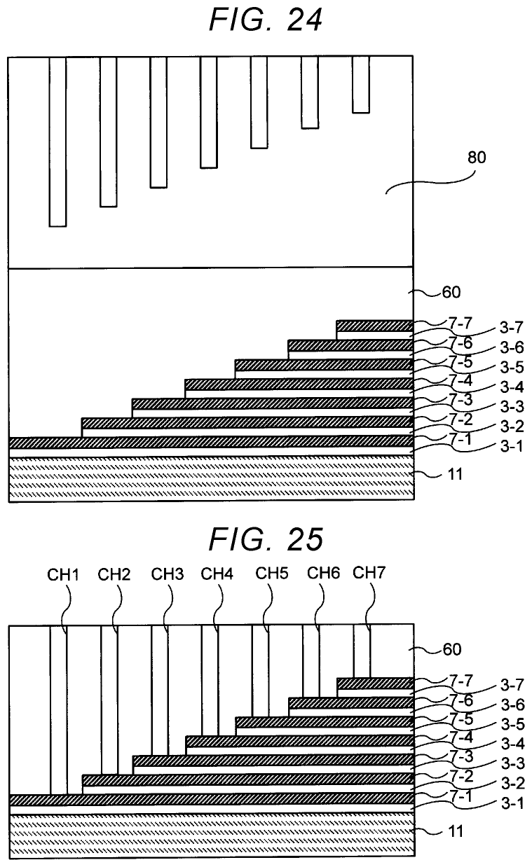

As illustrated in FIG. 24, by releasing the template 1a, the upper surface of the insulator 80 is flattened and the pattern of the plurality of contact holes CH different in depth is formed.

As illustrated in FIG. 25, the insulator 60 is processed using the insulator 80 including the pattern of the plurality of contact holes CH different in depth as a mask. The insulator 80 and the insulator 60 may be removed in part by, for example, anisotropic etching such as RIE. The pattern of the plurality of contact holes CH different in depth of the insulator 80 is transferred to the insulator 60. The formed contact holes CH1, CH2, CH3, CH4, CH5, CH6, and CH7 are different in depth from the upper surface of the insulator 60. The bottom portion (contact region) of the contact hole CH exposes the upper surface of the conductive layer 70.

The contact plug 50 illustrated in FIG. 21 is formed by embedding a metal such as tungsten in the contact hole CH exposing the conductive layer 70 corresponding to the bottom portion.

In the method for manufacturing the stacked wiring structure of the semiconductor device according to the present embodiment, the contact holes CH different in depth (gradation) can be patterned at once in the insulator 60 by nanoimprint lithography using the template 1a according to the present embodiment, and manufacturing efficiency and accuracy can be improved. Since the template 1a according to the present embodiment has the upper surface c of the protrusion portion H substantially parallel to the contact region of the conductive layer 70, contact can be satisfactory and the reliability of the semiconductor device can be improved.

### Third Embodiment

The configuration of the template according to the present embodiment is the same as the configuration of the template according to the second embodiment. The template pattern forming method according to the present embodiment is the same as the template pattern forming method according to the second embodiment except that the second layer 200 includes a first film 210 and a second film 220. The configuration of the stacked wiring structure according to the present embodiment is the same as the configuration of the stacked wiring structure according to the second embodiment. The stacked wiring structure manufacturing method according to the present embodiment is the same as the configuration of the stacked wiring structure according to the second embodiment. Descriptions that are the same as in the first and second embodiments are omitted, and differences from the first and second embodiments will be described here.

### [Pattern Forming Method]

The template manufacturing method according to the present embodiment, particularly a template pattern forming method, will be described with reference to FIGS. 26 to 36. It should be noted that although FIGS. 26 to 36 illustrate an example of forming the protrusion portions H different in height in the left-right direction of the paper, the method for forming the pattern 2a according to the present embodiment is also applicable in the depth direction of the paper.

As illustrated in FIG. 26, a stacked body is prepared in which the first layer 100, the second layer 200, and the third layer 300 are stacked in this order. Methods for manufacturing the stacked body are not particularly limited. The first layer 100, the second layer 200, and the third layer 300 are in contact with each other. The second layer 200 includes the first film 210 in contact with the first layer 100 and the second film 220 in contact with the first film 210. In the present embodiment, the first film 210 may function as a hard mask, and the material of the first film 210 may be, for example, a metal compound containing chromium or tantalum. The second film 220 may also function as a hard mask, and the material of the second film 220 may be, for example, a compound containing carbon or silicon.

The inclined portion C3 is formed on the surface 301, which is on the side opposite to the second film 220, of the third layer 300, which is in contact with the second film 220. The method for forming the inclined portion C3 is the same as that of the second embodiment and thus is omitted here.

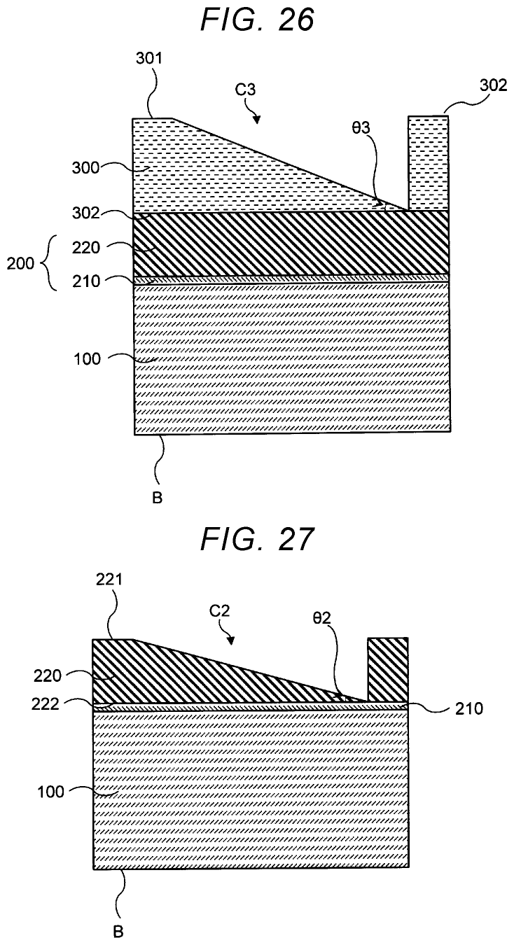

As illustrated in FIG. 27, the second film 220 of the second layer 200 is processed using the third layer 300 including the inclined portion C3 as a mask. The inclined portion C2 determined by the processing speeds of the third layer 300 and the second film 220 is transferred to the second film 220. For example, if the third layer 300 is higher in processing speed than the second film 220, the angle θ2 between a surface 222 of the second film 220 in contact with the first film 210 and the inclined portion C2 is smaller than the angle θ3 between the surface 302 of the third layer 300 in contact with the second layer 200 and the inclined portion C3. For example, if the second film 220 is higher in processing speed than the third layer 300, the angle θ2 between the surface 222 of the second film 220 and the inclined portion C2 is larger than the angle θ3 between the surface 302 of the third layer 300 and the inclined portion C3.

As illustrated in FIG. 28, the fourth layer 400 is formed on the second film 220 including the inclined portion C2 so as to fill the inclined portion C2.

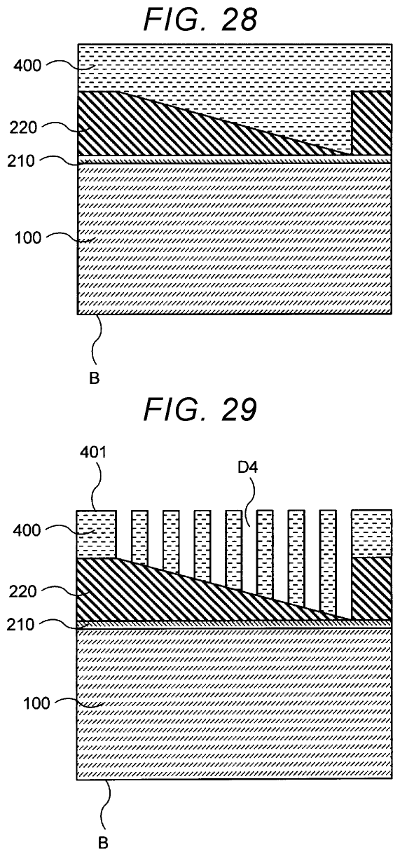

As illustrated in FIG. 29, the recessed portion D4 is formed in the surface 401, which is on the side opposite to the second film 220, of the fourth layer 400, which is in contact with the second film 220. The recessed portion D4 is formed on the inclined portion C2 using the inclined portion C2 of the second film 220 as a stopper. The recessed portion D4 exposes the inclined portion C2 of the second film 220.

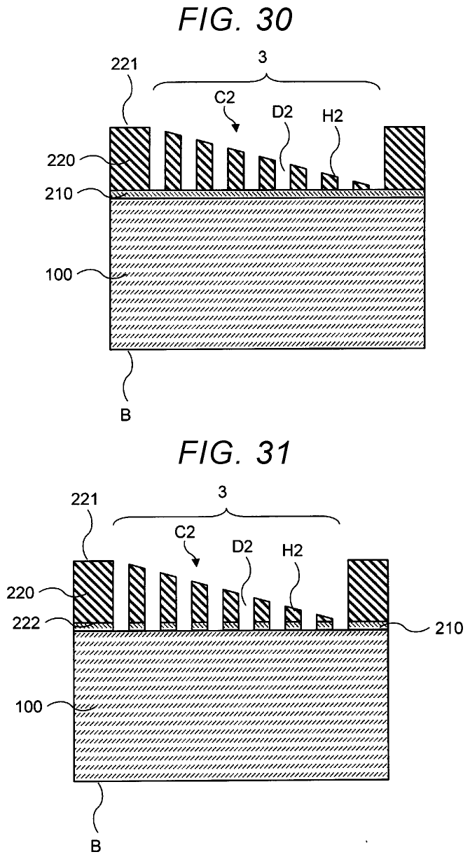

As illustrated in FIG. 30, the second film 220 is processed using the fourth layer 400 including the recessed portion D4 as a mask. The recessed portion D2 is transferred to the inclined portion C2 of the second film 220 using the first film 210 as a stopper, and the pattern 3 including the recessed portion D2 is formed in the inclined portion C2. The recessed portion D2 exposes the first film 210 at the bottom portion of the recessed portion D2. The thickness of the fourth layer 400 is appropriately set depending on the processing speeds of the fourth layer 400 and the second film 220 and the thickness of the second film 220. After that, the remaining fourth layer 400 is peeled off. By the pattern forming method according to the present embodiment, it is possible to form the pattern 3 having the protrusion portions H2 different in height on the first film 210 by forming the recessed portion D2 in the inclined portion C2 of the second film 220.

As illustrated in FIG. 31, the first film 210 is processed using the second film 220 including the pattern 3 as a mask. The first film 210 exposed by the recessed portion D2 of the pattern 3 is removed by etching using the first layer 100 as a stopper. At this time, the second film 220 is also reduced by etching. The processing amount of the first film 210 in this etching is larger than the processing amount of the second film 220. In other words, the processing speed of the first film 210 in this etching is higher than the processing speed of the second film 220 in this etching. The first layer 100 is exposed below the recessed portion D2 of the pattern 3 by the first film 210 being removed in part.

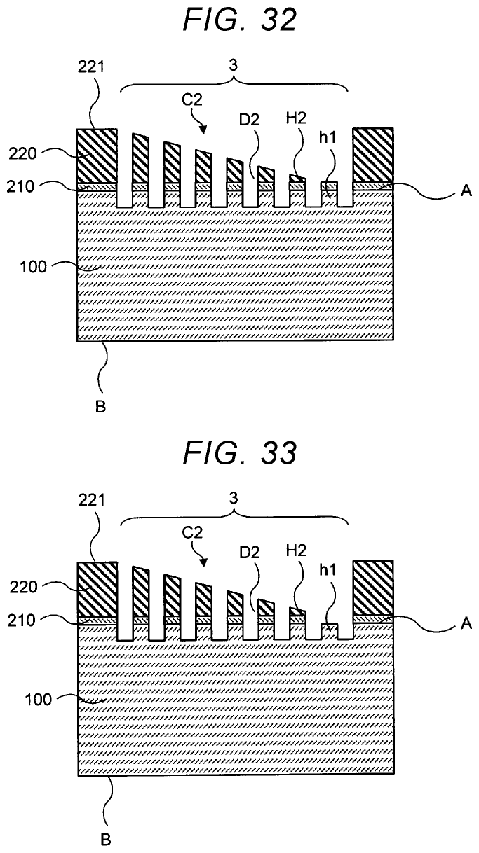

As illustrated in FIG. 32, processing (first etching) is performed to partially remove the first layer 100 using the second film 220 including the pattern 3 as a mask. The first layer 100 exposed by the recessed portion D2 of the pattern 3 is etched by the first etching. At this time, the second film 220 is also reduced by the first etching. The first etching may be, for example, RIE using a fluorine-based reaction gas. By the first etching, the lowest protrusion portion H2 in the inclined portion C2 is removed and the first film 210 is exposed. In other words, by the first etching, the thinnest second film 220 is removed and the first film 210 is exposed. The processing amount of the second film 220 in the first etching is larger than the processing amount of the first film 210. In other words, the processing speed of the second film 220 in the first etching is higher than the processing speed of the first film 210 in the first etching.

As illustrated in FIG. 33, processing (third etching) is performed to remove the first film 210 exposed by the first etching using the first layer 100 as a stopper. The processing amount of the first film 210 in the third etching is larger than the processing amount of the second film 220. In other words, the processing speed of the first film 210 in the third etching is higher than the processing speed of the second film 220 in the third etching. The processing amount of the first film 210 in the third etching is larger than the processing amount of the first layer 100. In other words, the processing speed of the first film 210 in the third etching is higher than the processing speed of the first layer 100 in the third etching. The third etching may be, for example, RIE using a chlorine-based reaction gas. By the third etching, the first film 210 exposed by the first etching is removed and the first surface A of the first layer 100 is exposed. After the first film 210 is removed, the protrusion portion h1 of the first layer 100 is formed.

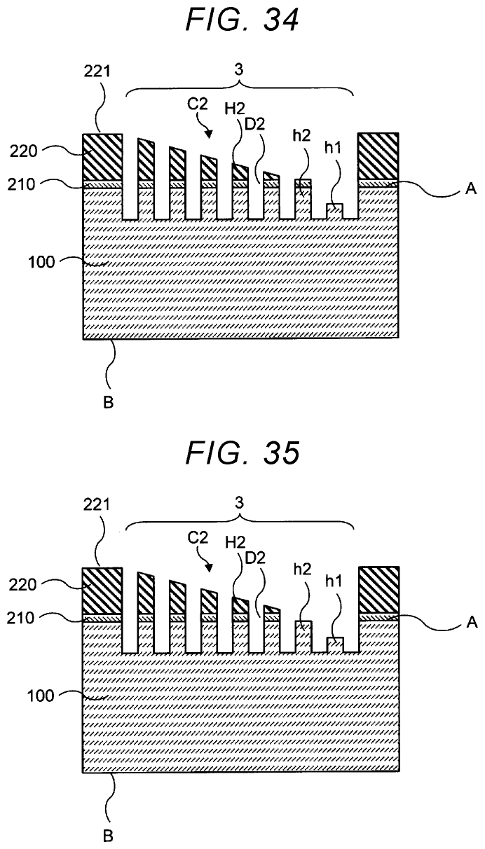

As illustrated in FIG. 34, using the remaining second film 220 including a part of the pattern 3 as a mask, the processing (first etching) is performed again to partially remove the first layer 100. The first layer 100 exposed by the recessed portion D2 of the pattern 3 is etched by the first etching. The protrusion portion h1 after the removal of the first film 210 is also etched substantially parallel to the first surface A by the first etching. At this time, the second film 220 is also reduced by the first etching. By the first etching, the second-lowest protrusion portion H2 in the inclined portion C2 is removed and the first film 210 is exposed. In other words, by the first etching, the second-thinnest second film 220 is removed and the first film 210 is exposed.

As illustrated in FIG. 35, processing (third etching)

is performed to remove the first film 210 exposed by the first etching using the first layer 100 as a stopper. By the third etching, the first film 210 exposed by the first etching is removed and the first surface A of the first layer 100 is exposed. After the first film 210 is removed, the protrusion portion h2 of the first layer 100 is formed.

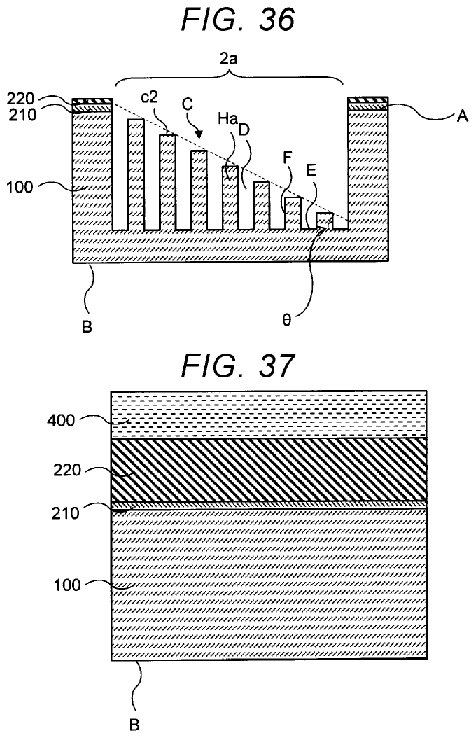

As illustrated in FIG. 36, by repeating the first etching and the third etching by the gradation count of the pattern 3, the pattern 2a including the recessed portion D in the inclined portion C determined by the processing speeds of the first layer 100 and the second film 220 is transferred to the surface A of the first layer 100. For example, if the first layer 100 is higher in processing speed than the second film 220, the angle θ between the bottom surface E of the recessed portion D and the inclined portion C is larger than the angle θ2 between the surface 222 of the second film 220 and the inclined portion C2, and the depth of the recessed portion D from the surface A to the bottom surface E is larger than the depth of the recessed portion D2 from a surface 221 to the surface 222. In other words, it is possible to form the pattern 2a, which is equivalent to the pattern 3 expanded in the stacking direction and has the protrusion portions Ha different in height on the bottom surface E. The thickness of the second film 220 and the angle θ2 between the surface 222 of the second film 220 and the inclined portion C2 (gradation count of the pattern 3) are appropriately set depending on, for example, the processing speeds of the first layer 100 and the second film 220 in the first etching, the disposition of the recessed portion D or the protrusion portion Ha of the pattern 2a, the angle θ between the bottom surface E of the recessed portion D and the inclined portion C (gradation count of the pattern 2a), the height from the bottom surface E to the surface A (height of the pattern 2a), the depth of the recessed portion D from the surface A to the bottom surface E (depth of the pattern 2a), the accuracy of control of the processing amount of the first layer 100 in the first etching, the processing speeds of the first layer 100, the first film 210, and the second film 220 in the third etching, and the processing amount buffer of the second film 220 in the third etching. After that, it is possible to manufacture the template 1a illustrated in FIG. 15 by peeling off the remaining first film 210 and second film 220.

By the template manufacturing method according to the present embodiment, it is possible to improve the formation efficiency and accuracy of the pattern 2a including the plurality of protrusion portions Ha different in height (gradation) on the bottom surface E of the recessed portion D.

### Fourth Embodiment

The configuration of the template according to the present embodiment is the same as the configuration of the template according to the second embodiment. The template pattern forming method according to the present embodiment is the same as the template pattern forming method according to the third embodiment except for the method for forming the pattern of the second film 220. The configuration of the stacked wiring structure according to the present embodiment is the same as the configuration of the stacked wiring structure according to the second embodiment. The stacked wiring structure manufacturing method according to the present embodiment is the same as the configuration of the stacked wiring structure according to the second embodiment. Descriptions that are the same as in the first to third embodiments are omitted, and differences from the first to third embodiments will be described here.

### [Pattern Forming Method]

The template manufacturing method according to the present embodiment, particularly a template pattern forming method, will be described with reference to FIGS. 37 to 42. It should be noted that although FIGS. 37 to 42 illustrate an example of forming the protrusion portions H different in height in the left-right direction of the paper, the method for forming the pattern 2a according to the present embodiment is also applicable in the depth direction of the paper.

As illustrated in FIG. 37, a stacked body is prepared in which the first layer 100, the second layer 200, and the fourth layer 400 are stacked in this order. Methods for manufacturing the stacked body are not particularly limited. The first layer 100, the second layer 200, and the fourth layer 400 are in contact with each other. The second layer 200 includes the first film 210 in contact with the first layer 100 and the second film 220 in contact with the first film 210.

As illustrated in FIG. 38, the recessed portion D4 is formed in the surface 401, which is on the side opposite to the second film 220, of the fourth layer 400, which is in contact with the second film 220. The recessed portion D4 is formed on the second film 220 using the second film 220 as a stopper. The recessed portion D4 exposes the second film 220.

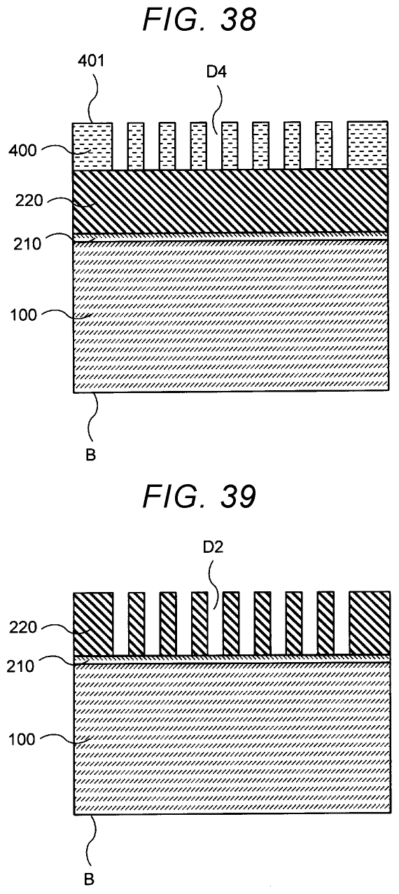

As illustrated in FIG. 39, the second film 220 is processed using the fourth layer 400 including the recessed portion D4 as a mask. The recessed portion D2 is transferred to the second film 220 using the first film 210 as a stopper. The recessed portion D2 exposes the first film 210 at the bottom portion of the recessed portion D2. The thickness of the fourth layer 400 is appropriately set depending on the processing speeds of the fourth layer 400 and the second film 220 and the thickness of the second film 220. After that, the remaining fourth layer 400 is peeled off.

As illustrated in FIG. 40, the third layer 300 is formed on the second film 220 including the recessed portion D2 so as to fill the recessed portion D2.

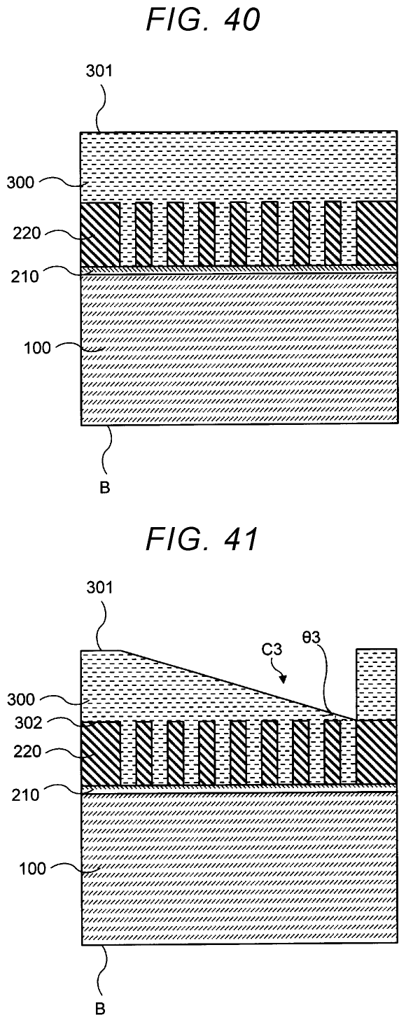

As illustrated in FIG. 41, the inclined portion C3 is formed on the surface 301, which is on the side opposite to the second film 220, of the third layer 300, which is in contact with the second film 220. The method for forming the inclined portion C3 is the same as that of the second embodiment and thus is omitted here.

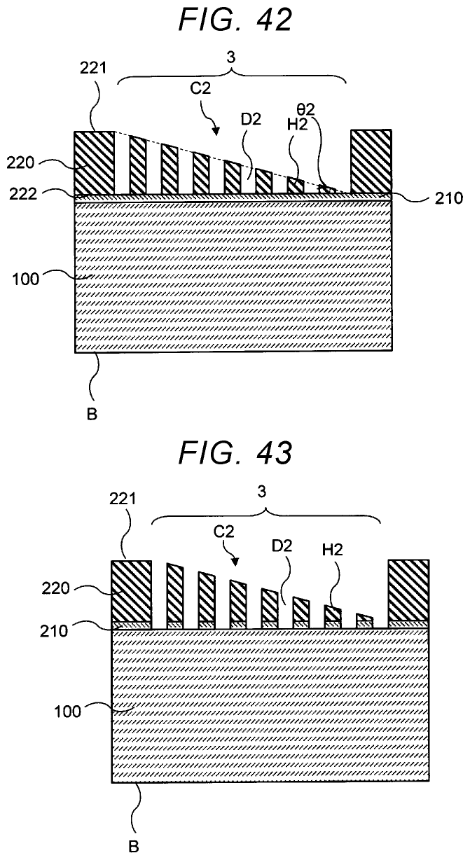

As illustrated in FIG. 42, the second film 220 including the recessed portion D2 is processed using the third layer 300 including the inclined portion C3 as a mask. The inclined portion C2 determined by the processing speeds of the third layer 300 and the second film 220 is transferred to the second film 220, and the pattern 3 including the inclined portion C2 is formed in the recessed portion D2. For example, if the third layer 300 is higher in processing speed than the second film 220, the angle θ2 between the surface 222 of the second film 220 in contact with the first film 210 and the inclined portion C2 is smaller than the angle θ3 between the surface 302 of the third layer 300 in contact with the second film 220 and the inclined portion C3. For example, if the second film 220 is higher in processing speed than the third layer 300, the angle θ2 between the surface 222 of the second film 220 and the inclined portion C2 is larger than the angle θ3 between the surface 302 of the third layer 300 and the inclined portion C3. By the pattern forming method according to the present embodiment, it is possible to form the pattern 3 having the protrusion portions H2 different in height on the first film 210 by forming the inclined portion C2 in the recessed portion D2 of the second film 220.

As illustrated in FIG. 43, the first film 210 is processed using the second film 220 including the pattern 3 as a mask. The first film 210 exposed by the recessed portion D2 of the pattern 3 is removed by etching using the first layer 100 as a stopper. At this time, the second film 220 is also reduced by etching. The processing amount of the first film 210 in this etching is larger than the processing amount of the second film 220. In other words, the processing speed of the first film 210 in this etching is higher than the processing speed of the second film 220 in this etching. The first layer 100 is exposed below the recessed portion D2 of the pattern 3 by the first film 210 being removed in part.

The method for forming the pattern 2a including the recessed portion D in the inclined portion C determined by the processing speeds of the first layer 100 and the second film 220 on the surface A of the first layer 100 is the same as the template pattern forming method according to the third embodiment (FIGS. 30 to 34), and thus redundant description is omitted here. It is possible to manufacture the template 1a illustrated in FIG. 14 by peeling off the remaining first film 210 and second film 220.

By the template manufacturing method according to the present embodiment, it is possible to improve the formation efficiency and accuracy of the pattern 2a including the plurality of protrusion portions Ha different in height (gradation) on the bottom surface E of the recessed portion D.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

Even in the case of other actions and effects different from those resulting from the aspects of the embodiments described above, it is a matter of course that those obvious from the description of this specification or those easily predictable by those skilled in the art are understood to result from the present disclosure.

What is claimed is:

1. A pattern forming method comprising:
forming a second layer over a first layer;
forming a first pattern along a surface of the second layer opposite to the first layer, the first pattern including an inclined portion with a recessed portion; and
forming a second pattern on the first layer by performing, with the second layer as a mask, a first etching process to remove a part of the first layer.

2. The pattern forming method according to claim 1,
wherein the step of forming a first pattern includes:
forming the inclined portion on the surface of the second layer, and
forming the recessed portion exposing the first layer in the inclined portion.

3. The pattern forming method according to claim 2, further comprising performing a second etching process to remove a part of the second layer and a part of a top surface of the first layer is exposed by the second etching process.

4. The pattern forming method according to claim 2, wherein
the second layer includes a first film in contact with the first layer and a second film in contact with the first film, and
the second film is higher than the first film in processing speed in the first etching process.

5. The pattern forming method according to claim 4, further comprising:
exposing a part of the first film through the first etching process; and
performing a third etching process to remove a part of the first film.

6. The pattern forming method according to claim 3, wherein the first pattern is set based on at least one of: processing speeds of the first layer and the second layer in the first etching process, disposition of the second pattern, a gradation count of the second pattern, a height of the second pattern, a depth of the second pattern, or a processing amount buffer of the second layer in the second etching process.

7. The pattern forming method according to claim 5, wherein the first pattern is set based on at least one of: processing speeds of the first layer and the second layer in the first etching process, disposition of the second pattern, a gradation count of the second pattern, a height of the second pattern, a depth of the second pattern, the processing speeds of the first film and the second film in the third etching process, and a processing amount buffer of the second film in the third etching process.

8. The pattern forming method according to claim 2,
wherein the step of forming a first pattern includes:
forming a first resin layer having an inclination on the second layer,
forming the inclined portion by transferring the inclination to the second layer,
forming a second resin layer having a recessed portion exposing the inclined portion on the second layer, and
removing a part of the second layer using the second resin layer as a mask.

9. The pattern forming method according to claim 1, wherein
the second layer includes a first film in contact with the first layer and a second film in contact with the first film, and
the step of forming a first pattern includes:
forming the recessed portion exposing the first film in the second film, and
forming the inclined portion on the second film.

10. The pattern forming method according to claim 9,
wherein the step of forming a first pattern includes:
forming a second resin layer having a recessed portion exposing the second film on the second film,
removing a part of the second layer using the second resin layer as a mask,
forming a first resin layer having an inclination on the second film, and
forming the inclined portion by transferring the inclination to the second film.

11. A template manufacturing method comprising:
forming a first layer over a substrate;
forming a first pattern along a surface of the first layer opposite to the substrate, the first pattern including an inclined portion with a recessed portion; and
forming a second pattern on the substrate by performing, with the first layer as a mask, a first etching process to remove a part of the substrate.

12. A semiconductor device manufacturing method comprising:
providing a stacked body including a plurality of third layers and a plurality of insulating layers alternately stacked on a semiconductor substrate;
providing a template through (i) forming a first pattern including an inclined portion and a recessed portion along a surface of a first layer provided on a substrate; and (ii) forming a second pattern on the substrate by performing a first etching process to remove a part of the substrate using the first layer as a mask;
applying an insulator to cover the stacked body;
using the template to imprint a first hole exposing one of the plurality of third layers and a second hole different in depth from the first hole and exposing another one of the plurality of third layers in the insulator; and
forming a conductor in the first hole and the second hole.

13. The pattern forming method according to claim 1, wherein the recessed portion includes a plurality of recesses extending into the second layer, the plurality of recesses having respectively different depths.

14. The template manufacturing method according to claim 11, wherein the recessed portion includes a plurality of recesses extending into the second layer, the plurality of recesses having respectively different depths.

15. The semiconductor device manufacturing method according to claim 12, wherein the recessed portion includes a plurality of recesses extending into the second layer, the plurality of recesses having respectively different depths.
